(19) United States
(12) Patent Application Publication
(10) Pub. No.: US 2009/0011344 A1
(43) Pub. Date: Jan. 8, 2009

(54) METHOD OF MANUFACTURING COLOR FILTER

(75) Inventors: Sung-woong Kim, Suwon-si (KR); Jung-yong Lee, Seongnam-si (KR); Tae-woon Cha, Seoul (KR)

Correspondence Address: STANZIONE & KIM, LLP, 919 18TH STREET, N.W., SUITE 440, WASHINGTON, DC, 20006, US

(73) Assignee: Samsung Electronics Co., Ltd., Suwon-si (KR)

(21) Appl. No.: 11/923,693

(22) Filed: Oct. 25, 2007

(30) Foreign Application Priority Data
Jul. 2, 2007 (KR) 2007-66178

(51) Int. Cl. G03F 3/00

(52) U.S. Cl. 430/7

(57) ABSTRACT

A method of manufacturing a color filter including providing pixels defined by a black matrix on a substrate, forming a liquid ink layer in the pixels, drying the liquid ink layer to form a film on a surface of the liquid ink layer, coating an overcoating solution on the film of the liquid ink layer, and hard baking the liquid ink layer and the overcoating solution in order to form a solidified ink layer adhered to a solidified overcoating layer without discoloration of the pixels.

### CROSS-REFERENCE TO RELATED APPLICATIONS

This application claims the benefit of Korean Patent Application No. 10-2007-0066178, filed on Jul. 2, 2007, in the Korean Intellectual Property Office, the disclosure of which is incorporated herein in its entirety by reference.

### BACKGROUND OF THE INVENTION

1. Field of the Invention

The present general inventive concept relates to a method of manufacturing a color filter, and more particularly, to a method of manufacturing in which a manufacturing process can be simplified and adhesive strength can be increased between an ink layer and an overcoating layer.

2. Description of the Related Art

Conventionally, cathode ray tube (CRT) monitors have been generally used to display image information for televisions and computers. However, as the size of the monitors has been increasing, flat panel displays such as liquid crystal displays (LCDs), plasma display panels (PDPs), organic light emitting diodes (OLEDs), light emitting diode (LED) displays, or field emission displays (FEDs) are increasingly being used. Of the flat panel displays, LCDs, which are mainly used in computer monitors or personal computer notebooks, have drawn much attention due to their low power consumption.

An LCD includes a color filter that forms a desired color image by transmitting white light modulated by a liquid crystal layer. The color filter has a structure in which a plurality of red R, green G and blue B pixels are arranged in a predetermined pattern on a transparent substrate. The pixels are defined based on a black matrix. To manufacture the color filter, a dyeing method, a pigment dispersion method, a printing method, or an electrode position method has been conventionally used. Recently, an inkjet method has been proposed since this method is simple, and thus, can reduce manufacturing costs. In a method of manufacturing a color filter using the inkjet method, a color filter is manufactured by ejecting ink droplets of a predetermined color, for example, red R, green G and blue B color, in the pixels through an inkjet head.

FIGS. 1 through 3 are views illustrating a conventional method of manufacturing a color filter using a printing method or an inkjet method. First, referring to FIG. 1, red, green and blue liquid ink layers 30R′, 30G′ and 30B′ are formed in pixels defined by a black matrix 20 on a substrate 10 using a printing method or an inkjet method. The liquid ink layers 30R′, 30G′ and 30B′ may be formed of a thermosetting resin. By hard baking the liquid ink layers 30R′, 30G′ and 30B′ at a high temperature of about 200° C or more, the liquid ink layers 30R′, 30G′ and 30B′ can be solidified. Next, referring to FIG. 2, to improve adhesive strength between each of a solidified ink layers 30R, 30G and 30B and an overcoating layer (50 of FIG. 3) formed thereon, a UV ashing process, in which ultraviolet rays are irradiated, is performed with respect to a surface of each of the solidified ink layers 30R, 30G and 30B. Next, referring to FIG. 3, an overcoating solution is coated on the solidified ink layers 30R, 30G and 30B by hard baking a resulting structure, forming an overcoating layer 50. An ITO electrode (not shown) may be formed on the overcoating layer 50, as well.

However, in the above conventional method of manufacturing a color filter, since a binder or the like present in the solidified ink layers 30R, 30G and 30B can deteriorate due to the UV ashing process, problems such as discoloration can occur. In the process in which the overcoating layer 50 is formed through the hard baking process, the adhesive strength between each of the solidified ink layers 30R, 30G and 30B and the overcoating layer 50 can be reduced by non-reactive material or solvent remaining in the solidified ink layers 30R, 30G and 30B. In addition, the above process may cause protrusions or cracks to be generated on the surface of the overcoating layer 50.

### SUMMARY OF THE INVENTION

The present general inventive concept provides a method of manufacturing a color filter, in which a manufacturing process can be simplified and adhesive strength between an ink layer and an overcoating layer can be increased.

Additional aspects and utilities of the present general inventive concept will be set forth in part in the description which follows and, in part, will be obvious from the description, or may be learned by practice of the general inventive concept.

The foregoing and/or other aspects and utilities of the present general inventive concept may be achieved by providing a method of manufacturing a color filter, the method including, providing pixels defined by a black matrix on a substrate, forming a liquid ink layer in the pixels, drying the liquid ink layer to form a film on a surface of the liquid ink layer; coating an overcoating solution on the film of the liquid ink layer, and hard baking the liquid ink layer and the overcoating solution to form a solidified ink layer and a solidified overcoating layer.

Drying the liquid ink layer to form the film may be performed by natural-drying the liquid ink layer or by soft-baking the liquid ink layer. The soft-baking may be performed at a temperature in the range of from 60 to 80° C. for a period of time in the range of from 30 seconds to one minute.

The film may be formed to prevent a solvent of the overcoating solution from permeating into the liquid ink layer.

At an interface between the solidified ink layer and the solidified overcoating layer which are formed using the hard baking a network structure may be formed by cross linking between a resin composition of the solidified ink layer and a resin composition of the overcoating layer. The hard baking may be performed at a temperature in the range of from 100 to 300° C. for a duration of from 30 minutes to 3 hours.

The liquid ink layer and the overcoating solution may include a thermosetting resin. The thermosetting resin may include a polymer binder and a cross linking agent.

The method of forming the liquid ink layer in the pixels may be performed using a printing method or an inkjet method. Coating the overcoating solution on the film may be performed by spin coating and/or slit coating.

The foregoing and/or other aspects and utilities of the present general inventive concept may be achieved by providing a color filter including a plurality of pixels formed on a substrate, an ink layer disposed within the pixels, a film formed on a surface of the ink layer, an overcoating layer formed on the film, and a network structure formed by cross linking the ink layer and the overcoating layer.

The film may be formed on a surface of the ink layer by drying the ink layer.

The network structure may be formed by solidifying the ink layer and the overcoating layer.

The ink layer disposed within the pixels may be a liquid ink layer.

The liquid ink layer and the overcoating layer may be hard baked to form a solidified ink layer and a solidified overcoating layer.

The network structure may be formed by cross linking between a resin compound of the solidified ink layer and a resin compound of the solidified overcoating layer.

### BRIEF DESCRIPTION OF THE DRAWINGS

These and/or other aspects and utilities of the present general inventive concept will become apparent and more readily appreciated from the following description of the embodiments, taken in conjunction with the accompanying drawings of which:

FIGS. 1 through 3 are views illustrating a conventional method of manufacturing a color filter using a printing method or an inkjet method; and

FIGS. 4 through 7 are views illustrating a method of manufacturing a color filter, according to an embodiment of the present general inventive concept.

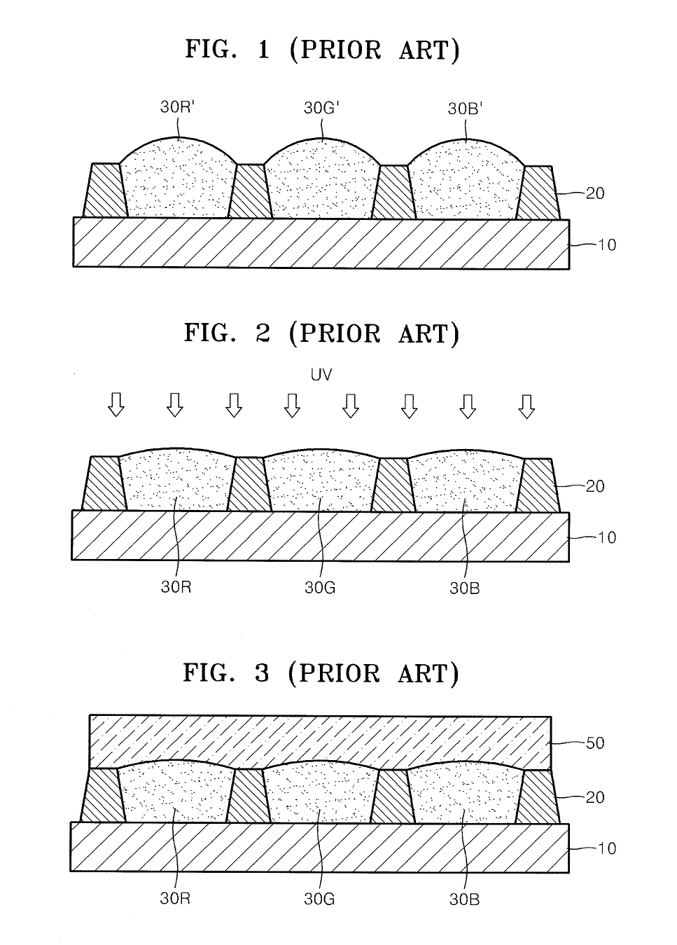

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

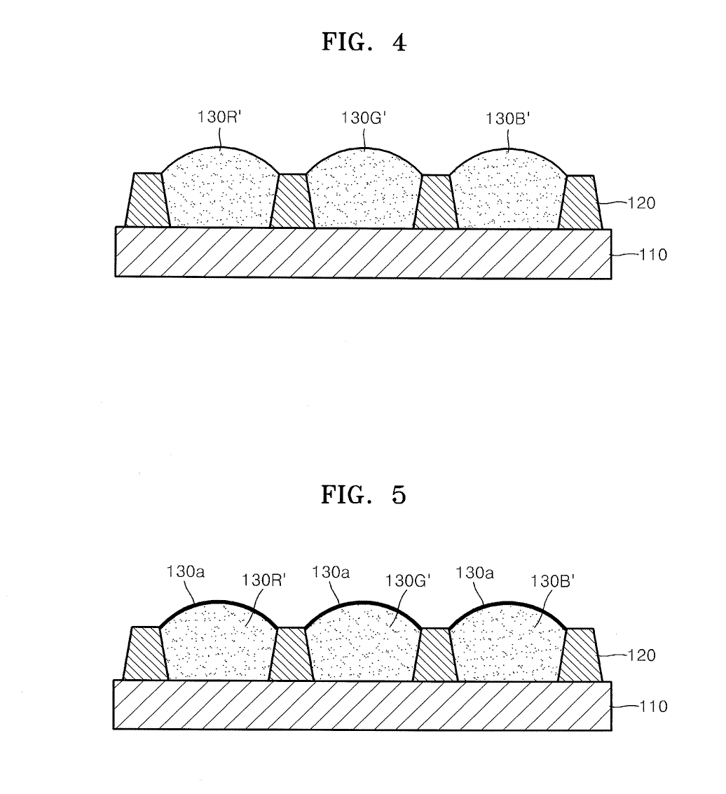

FIGS. 4 through 7 are views illustrating a method of manufacturing a color filter, according to an embodiment of the present general inventive concept.

First, referring to FIG. 4, a matrix 120 is formed on a substrate 110. The matrix 120 may be a black matrix. The substrate 110 may be a transparent glass substrate. The black matrix 120 may be formed by a method including forming a predetermined shielding material layer (not shown) on the substrate 110 and patterning the shielding material layer. A plurality of pixels are defined on the substrate 110 by the black matrix 120. Next, for example, red, green and blue liquid ink layers 130R′, 130G′ and 130B′ are formed in the pixels. The liquid ink layers 130R′, 130G′ and 130B′ may be formed of a thermosetting resin. The thermosetting resin includes a polymer binder, a cross linking agent or the like. The liquid ink layers 130R′, 130G′ and 130B′ may be formed using various printing methods or an inkjet method. When the inkjet method is used, the liquid ink layers 130R′, 130G′ and 130B′ may be formed by ejecting ink drops having predetermined colors from an inkjet head into the pixels.

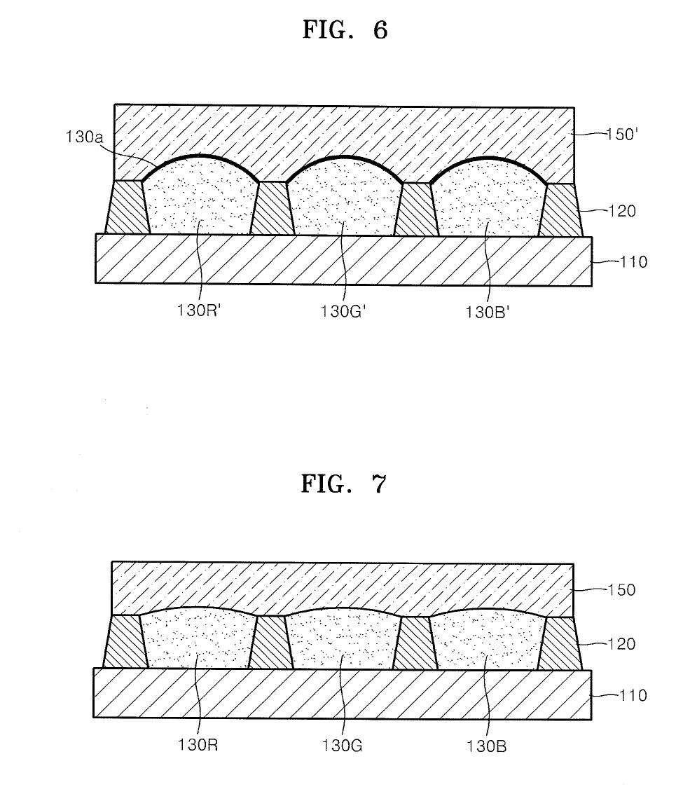

Referring to FIG. 5, a film 130a is formed on the liquid ink layers 130R′, 130G′ and 130B′ by drying the liquid ink layers 130R′, 130G′ and 130B′ formed in the pixels. The film 130a is formed so that a solvent of an overcoating solution 150′ (refer to FIG. 6), which is coated on the film 130 in the following operation, may not permeate into the liquid ink layers 130R′, 130G′ and 130B′. The film 130a may be formed by natural-drying or soft-baking the liquid ink layers 130R′, 130G′ and 130B′. The soft-baking may be performed by heating the liquid ink layers 130R′, 130G′ and 130B′ at a temperature in the range of from 60 to 80° C. for a period of time in the range of from 30 seconds to one minute. However, the present general inventive concept is not limited thereto.

Referring to FIG. 6, the overcoating solution 150′ is coated on the liquid ink layers 130R′, 130G′ and 130B′ on which the film 130a has been formed. The overcoating solution 150′ may be formed of a thermosetting resin, like the liquid ink layers 130R′, 130G′ and 130B′. The thermosetting resin may include a polymer binder, a cross linking agent or the like. The overcoating solution 150′ may be coated on the liquid ink layers 130R′, 130G′ and 130B′, and on the black matrix 120, using a spin coating process or a slit coating process. In another embodiment, the overcoating solution 150′ may be coated using the spin coating process together with the slit coating process. In either embodiment, the overcoating solution 150′ is coated on the liquid ink layers 130R′, 130G′ and 130B′ so that the film 130a may be disposed between the overcoating solution 150′ and each of the liquid ink layers 130R′, 130G′ and 130B′. A solvent of the overcoating solution 150′ does not permeate into the liquid ink layers 130R′, 130G′ and 130B′ due to the presence of film 130a. If the film 130a is not formed on the liquid ink layers 130R′, 130G′ and 130B′, the solvent of the overcoating solution 150′ may permeate into the liquid ink layers 130R′, 130G′ and 130B′, and thus the overcoating solution 150′ and the liquid ink layers 130R′, 130G′ and 130B′ may be mixed with each other to cause color mixing and discoloration.

Referring to FIG. 7, a hard baking process is performed with respect to both the liquid ink layers 130R′, 130G′ and 130B′ and the overcoating solution 150′. The hard baking can be performed by heating the liquid ink layers 130R′, 130G′ and 130B′ and the overcoating solution 150′ at a temperature in the range of from 100 to 300° C. for a period of time in the range of from 30 minutes to 3 hours. However, the present general inventive concept is not limited thereto. Through the hard baking, the liquid ink layers 130R′, 130G′ and 130B′ in the pixels are solidified to form solidified ink layers 130R′, 130G′ and 130B′. The solidified overcoating layer 150 is formed on the solidified ink layers 130R′, 130G′ and 130B′. In addition, chemical coupling (i.e. cross linking) between a resin composition of the solidified ink layers 130R′, 130G′ and 130B′ and a resin composition of the solidified overcoating layer 150 occurs on an interface between each of the ink layers 130R′, 130G′ and 130B′ and the solidified overcoating layer 150 through the hard baking process. Accordingly, a network structure is formed on the interface between each of the ink layers 130R′, 130G′ and 130B′ and the solidified overcoating layer 150 due to the cross linking. Due to the formation of the network structure, adhesive strength between each of the ink layers 130R′, 130G′ and 130B′ and the solidified overcoating layer 150 can be remarkably increased.

As described above, a manufacturing process can be simplified by omitting a hard baking process and a UV ashing process that are performed after forming a liquid ink layer in a conventional art.

According to the present embodiment, by forming a network structure on an interface between a solidified ink layer and an overcoating layer due to cross linking, adhesive strength between the ink layer and the overcoating layer can be remarkably increased, and thus the durability of a color filter can be improved.

As described above, there are problems due to a non-reactive material or a remaining solvent in an ink layer in a conventional process in which an overcoating layer is formed using a hard baking process. According to the present invention, the problems can be removed.

According to the present general inventive concept, by omitting a UV ashing process performed in order to improve adhesive strength in a conventional art, problems such as discoloration can be solved.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A method of manufacturing a color filter, the method comprising:
providing pixels defined by a black matrix on a substrate;
forming a liquid ink layer in the pixels;
drying the liquid ink layer to form a film on a surface of the liquid ink layer;
coating an overcoating solution on the film of the liquid ink layer; and
hard baking the liquid ink layer and the overcoating solution to form a solidified ink layer and a solidified overcoating layer.

2. The method of claim 1, wherein drying the liquid ink layer to form the film is performed by natural-drying the liquid ink layer the liquid ink layer.

3. The method of claim 1, wherein drying the liquid ink layer to form the film is performed by soft baking the liquid ink layer.

4. The method of claim 3, wherein the soft-baking is performed at a temperature in the range of from 60 to 80° C. for a period of time in the range of from 30 seconds to one minute.

5. The method of claim 1, wherein the film is formed to prevent a solvent of the overcoating solution from permeating into the liquid ink layer.

6. The method of claim 1, wherein at an interface between the solidified ink layer and the solidified overcoating layer which are formed using the hard baking a network structure is formed by cross linking between a resin composition of the solidified ink layer and a resin composition of the overcoating layer.

7. The method of claim 6, wherein the hard baking is performed at a temperature in the range of from 100 to 300° C. for a duration of from 30 minutes to 3 hours.

8. The method of claim 1, wherein the liquid ink layer and the overcoating solution include a thermosetting resin.

9. The method of claim 8, wherein the thermosetting resin comprises a polymer binder and a cross linking agent.

10. The method of claim 1, wherein forming the liquid ink layer in the pixels is performed using a printing method.

11. The method of claim 1, wherein forming the liquid ink layer in the pixels is performed using an inkjet method.

12. The method of claim 1, wherein coating the overcoating solution on the film is performed by spin coating and/or slit coating.

13. The method of claim 1, wherein providing the pixels is performed by forming the black matrix on the substrate.

14. The method of claim 13, wherein the black matrix is formed by forming a shielding material layer on the substrate and patterning the shielding material layer.
